(19) United States
(12) Patent Application Publication
(10) Pub. No.: US 2008/0020297 A1
(43) Pub. Date: Jan. 24, 2008

(54) Mask for photolithography and method of fabricating photoresist pattern using the same

(75) Inventors: Chang-hwan Kim, Gyeonggi-do (KR); Young-cheol Lim, Gyeonggi-do (KR); Young-seog Kang, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/803,080

(22) Filed: May 11, 2007

(30) Foreign Application Priority Data
Jul. 24, 2006 (KR) 10-2006-0069275
Oct. 31, 2006 (KR) 10-2006-0106719

(51) Int. Cl. G03F 1/00

(52) U.S. Cl. 430/5; 430/270.1

(57) ABSTRACT

A mask for photolithography with high exposure margin and a method of fabricating a photoresist pattern, using the mask are provided. The mask for photolithography includes a transparent substrate and a plurality of optical shielding members on the transparent substrate. Each optical shielding member includes a plurality of optical shielding layer segments which are separated from one another or which are connected to one another in their edges. The optical shielding member forms one image in which the optical shielding layer segments are connected to one another, upon photolithography.

### CROSS-REFERENCE TO RELATED PATENT APPLICATION

This application claims the benefit of Korean Patent Application Nos. 10-2006-0069275 and 10-2006-0106719, filed on Jul. 24, 2006, and Oct. 31, 2006, respectively, in the Korean Intellectual Property Office, the disclosure of which is incorporated herein in its entirety by reference.

### FIELD OF THE INVENTION

The present invention relates generally to semiconductor devices and, more particularly, to apparatus and methods for fabricating semiconductor devices.

### BACKGROUND OF THE INVENTION

Generally, a semiconductor device fabricating process includes a number of photolithography and etching processes to form patterns of circuit devices on a semiconductor substrate. The photolithography process transfers a pattern formed on a mask onto a semiconductor substrate using a photoresist layer.

As the integration density of a semiconductor device increases, the critical dimensions (CD) of a photoresist pattern become smaller. Accordingly, to form a photoresist pattern with micro CD, an exposure apparatus with high exposure margin is introduced. In an exposure apparatus, an off-axis illumination technology is used to increase the resolution and to improve the depth of focus (DOF) margin.

The off-axis illumination technology exposes a photoresist layer to light, controlling the angle of light being incident by selecting a proper illumination system for a pattern formed on a mask. The off-axis illumination technology may be effectively used for a one-dimensional pattern or when the pitch difference between a long axis and a short axis is not great. However, in the off-axis illumination technology, since an illumination system is focused on a pattern with a minimum pitch, it reduces the process margin in a two-dimensional pattern with different pitches.

FIG. 1 is a plan view of a conventional mask 100 for photolithography; and FIG. 2 is a plan view of an image 120a by simulation when photolithography is performed using the mask of FIG. 1.

Referring to FIG. 1, the mask 100 includes a transparent substrate 110 and a plurality of optical shielding layers 120 formed on the transparent substrate 110. The optical shielding layers 120 are disposed two-dimensionally, for example, in an X1-axis and an X2-axis. The pitch of the optical shielding layer 120 in the X2-axis is greater than the pitch in the X1-axis.

Referring to FIG. 2, the image 120a by simulation is illustrated. The X2-axial edge portions of the image 120a deviate from the pattern of the optical shielding layer 120 of the mask 100. In the image 120a, exposure latitude (EL) margins are calculated as about 7.82% in the X1-axial direction and as about 4.77% in the X2-axial axial direction. That is, the EL margin in the direction with a high pitch, i.e., in the X2-axial direction, is much lower than the EL margin in the direction with a low pitch, i.e., in the X1-axial direction.

The insufficient exposure margin may cause a short in a photoresist pattern and consequently the short in a circuit pattern, thereby seriously deteriorating the reliability of a semiconductor device.

### SUMMARY OF THE INVENTION

The present invention provides a mask for photolithography with high exposure margin.

The present invention also provides a method for fabricating a photoresist pattern with high reliability.

According to embodiments of the present invention, there is provided a mask for photolithography comprising a transparent substrate; and a plurality of optical shielding members on the transparent substrate. Each optical shielding member includes a plurality of optical shielding layer segments which are separated from one another, and each optical shielding member forms one image in which the plurality of optical shielding layer segments are connected to one another during a photolithography process.

The plurality of optical shielding members may be disposed at a first pitch in a first direction and at a second pitch in a second direction, and the second pitch may be greater than the first pitch. Further, the plurality of optical shielding layer segments may be disposed, along the second direction.

Each optical shielding layer segment included in each optical shielding member may include a through hole to expose the transparent substrate.

According to other embodiments of the present invention, there is provided a mask for photolithography comprising a transparent substrate; and a plurality of optical shielding members on the transparent substrate. Each optical shielding member includes a plurality of optical shielding layer segments which are connected to one another at their edges, to form one image during a photolithography process. A width of a connection part of the optical shielding layer segments is narrower than a width of the other part.

According to other embodiments of the present invention, there is provided a method of fabricating a photoresist pattern using the mask for photolithography. In accordance with the method, a photoresist layer is formed on a substrate. The photoresist layer is exposed to light, using the mask. The exposed photoresist layer is developed, to fabricate a photoresist pattern on a semiconductor device corresponding to an image.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view of a conventional mask for photolithography;

FIG. 2 is a plan view of an image by simulation when photolithography is performed using the mask of FIG. 1;

FIG. 3 is a plan view of a mask for photolithography in accordance with an embodiment of the present invention;

FIG. 4 is a plan view of an image by simulation when photolithography is performed using the mask of FIG. 3;

FIGS. 5 and 6 are graphs of the exposure margins of the image of FIG. 4 in a short axial direction and a long axial direction, respectively;

FIG. 7 is a plan view of a mask for photolithography in accordance with another embodiment of the present invention;

FIG. 8 is a plan view of an image by simulation when photolithography is performed using the mask of FIG. 7;

FIGS. 9 and 10 are graphs of the exposure margins of the image of FIG. 8 in a short axial direction and a long axial direction, respectively;

FIG. 11 is a plan view of a photoresist pattern after photolithography is performed using the mask of FIG. 7;

FIG. 12 is a plan view of a photoresist pattern after photolithography is performed using a mask in accordance with a comparative example;

FIG. 13 is a plan view of a mask for photolithography in accordance with another embodiment of the present invention;

FIG. 14 is a plan view of an image by simulation when photolithography is performed using the mask of FIG. 13;

FIG. 15 is a plan view of a mask for photolithography according to another embodiment of the present invention;

FIG. 16 is a plan view of a modified example of the mask for photography of FIG. 15;

FIG. 17 is a plan view of an image by simulation when photolithography is performed using the mask of FIG. 16; and

FIGS. 18 and 19 are graphs of the exposure margins of the image of FIG. 17 in a short axial direction and a long axial direction, respectively.

### DETAILED DESCRIPTION OF EMBODIMENTS OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the size of elements is exaggerated for clarity.

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Moreover, each embodiment described and illustrated herein includes its complementary conductivity type embodiment as well. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “below”, “lower”, “above”, “upper” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly. Moreover, the term “beneath” indicates a relationship of one layer or region to another layer or region relative to the substrate, as illustrated in the figures.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to plan and cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein, have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

According to embodiments of the present invention, a mask may be used during an exposure process applying photolithography technology. The mask for photolithography may be called a reticle, and this term does not limit the scope of the present invention. In the embodiments of the present invention, it may be understood that exposure margins include exposure latitude (EL), depth of focus (DOF) or normalized image log slope (NILS).

In the embodiments of the present invention, a short axial direction and a long axial direction may be respectively named a first direction and a second direction.

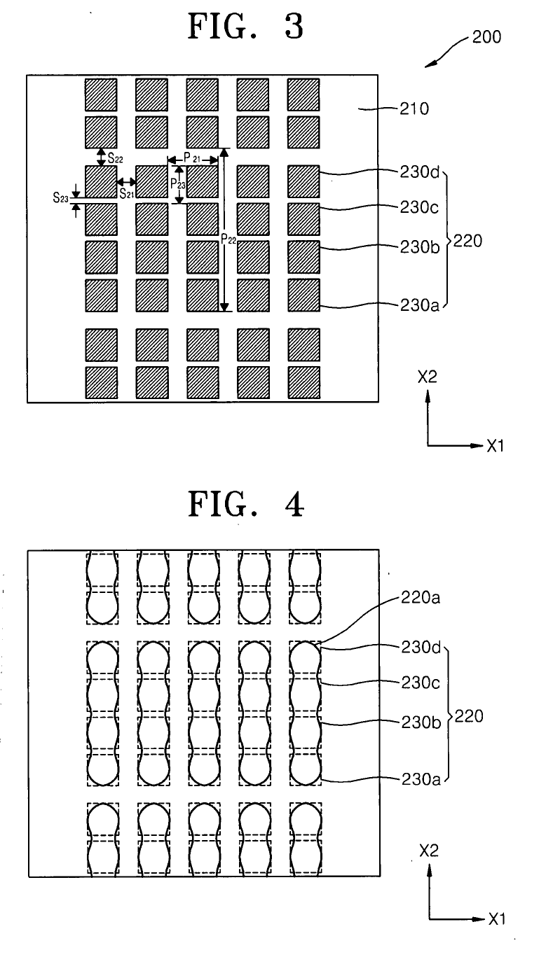

FIG. 3 is a plan view of a mask 200 for photolithography in accordance with an embodiment of the present invention. FIG. 4 is a plan view of an image 220a by simulation when photolithography is performed using the mask 200 of FIG. 3.

In FIG. 3, the mask 200 includes a transparent substrate 210 and a plurality of optical shielding members 220. For example, the optical shielding members 220 are formed in a repeating pattern on the transparent substrate 210. Each optical shielding member 220 includes a plurality of optical shielding layer segments 230a, 230b, 230c and 230d which are separated from one another. The optical shielding layer segments 230a, 230b, 230c and 230d included in each optical shielding member 220 are separated from one another on the mask 200 but are connected to one another during a photolithography process, to form one image. The optical shielding layer segments 230a, 230b, 230c and 230d may be provided to enhance the periodicity of arrangement of the optical shielding members 220.

For example, the transparent substrate 210 may include a glass substrate. The transparent substrate 210 allows light of a predetermined wavelength or electromagnetic radiation at other wavelengths to be transmitted. However, the optical shielding member 220 does not substantially allow the light (or electromagnetic radiation at other wavelengths) to be transmitted. For example, the optical shielding member 220 may include a chrome (Cr) layer. However, since the expression of ‘transmission of light’ is used in a relative meaning in this application, it shall not be interpreted that the optical shielding member 220 never allows light to be transmitted therethrough. For example, optical shielding member 220 may allow visible light at some wavelengths to pass therethrough and/or may allow electromagnetic radiation at various other wavelengths to pass therethrough.

The optical shielding members 220 may have a two-dimensional shape, i.e., a shape being elongated in both the X1-direction and X2-direction. In the embodiment illustrated in FIG. 3, the X1-direction indicates a short axial direction, and the X2-direction indicates a long axial direction. For example, the optical shielding member 220 may be disposed at a first pitch P₂₁ in the X1-direction and a second pitch P₂₂ in the X2-direction. As used herein, the term “pitch” means the distance between patterns, and may be a sum of the width and spacing of the patterns. As illustrated in FIG. 3, the second pitch P₂₂ may be greater than the first pitch P₂₁. A ratio of the second pitch P₂₂ to the first pitch P₂₁ may be appropriately selected, for example, at least 2:1 or more. The optical shielding members 220 may be spaced apart from one another, at a first space S₂₁ in the X1-direction and a second space S₂₂ in the X2-direction. The smaller the difference between the first space S₂₁ and the second space S₂₂ is, the more the efficiency of exposure using the mask 200 is improved.

The optical shielding layer segments 230a, 230b, 230c and 230d may have the same shape or similar shapes. To increase the exposure efficiency, the optical shielding layer segments 230a, 230b, 230c and 230d may be formed in symmetric and repeating shapes. For example, the optical shielding layer segments 230a, 230b, 230c and 230d may basically have square elements (not shown) for convenience when they are formed. In FIG. 3, an elongation direction of the square elements, i.e., the elongation direction of the optical shielding layer segments 230a, 230b, 230c and 230d, may be same as the elongation direction of the optical shielding members 220. In FIG. 3, the optical shielding layer segments 230a, 230b, 230c and 230d have the same shape but this does not limit the scope of the present invention. Optical shielding layer segments 230a, 230b, 230c and 230d may each have different shapes. According to some embodiments of the present invention, two or more of the optical shielding layer segments 230a, 230b, 230c and 230d may have different shapes from the other ones of the optical shielding layer segments 230a-230d.

The optical shielding layer segments 230a, 230b, 230c and 230d are disposed so as to be separated from one another in the X2-direction. That is, the optical shielding layer segments 230a, 230b, 230c and 230d are disposed to be separated in the direction in which the pitch of the optical shielding member 220 is relatively greater, for example, in the X2-direction. The optical shielding layer segments 230a, 230b, 230c and 230d are disposed to be spaced apart from one another, on the average, at a third space S₂₃ and a third pitch P₂₃. The third pitch P₂₃ may be similar to the first pitch P₂₁. For example, the difference between the third pitch P₂₃ and the first pitch P₂₁ may be within the range of 20% of the first pitch P₂₁.

Although the optical shielding members 220 are disposed so that the pitch in the X1-direction is different from the pitch in the X2-direction, the pitch difference between the X1-direction and the X2-direction almost disappears based on the optical shielding layer segments 230a, 230b, 230c and 230d. For example, P₂₃ is similar to P₂₁, although P₂₂ is much larger than P₂₁, because optical members 220 are each split into four segments 230a, 230b, 230c and 230d. Since the light which passes through the mask 200 is actually influenced by the optical shielding layer segments 230a, 230b, 230c and 230d as interference elements or diffraction elements, the pitch of each of the optical shielding layer segments 230a, 230b, 230c and 230d becomes important.

Further, an amount of light being transmitted between the optical shielding layer segments 230a, 230b, 230c and 230d should be less than an amount of the light being transmitted between the optical shielding members 220. Accordingly, the space between the optical shielding layer segments 230a, 230b, 230c and 230d, that is, the third space S₂₃, should be smaller than the first space S₂₁, and the second space S₂₂, and, for example, it may be at least ½ or less. The third space S₂₃ allows one image to be formed, as described later, and it may be further selected within a range of securing margins upon electron beam writing to form the mask 200. For example, when a ratio of projection of 1:1 is used, the third space S₂₃ may be selected within the range of about 20 nm±20% but the scope of the present invention shall not be limited thereto.

FIG. 4 illustrates the image 220a by simulation when photolithography is performed using the mask 200 of FIG. 3. In the simulation, an off-axis illumination system is used for an exposure process, and an ArF source is used to generate light. Although a wave shape is observed, it is noted that the optical shielding layer segments 230a, 230b, 230c and 230d are connected to one another, to form one image 220a.

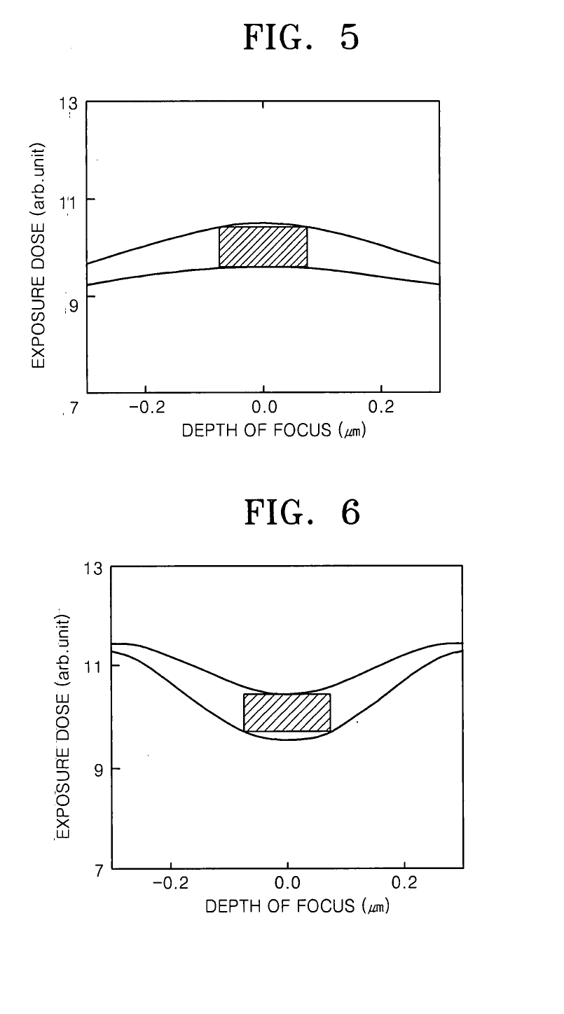

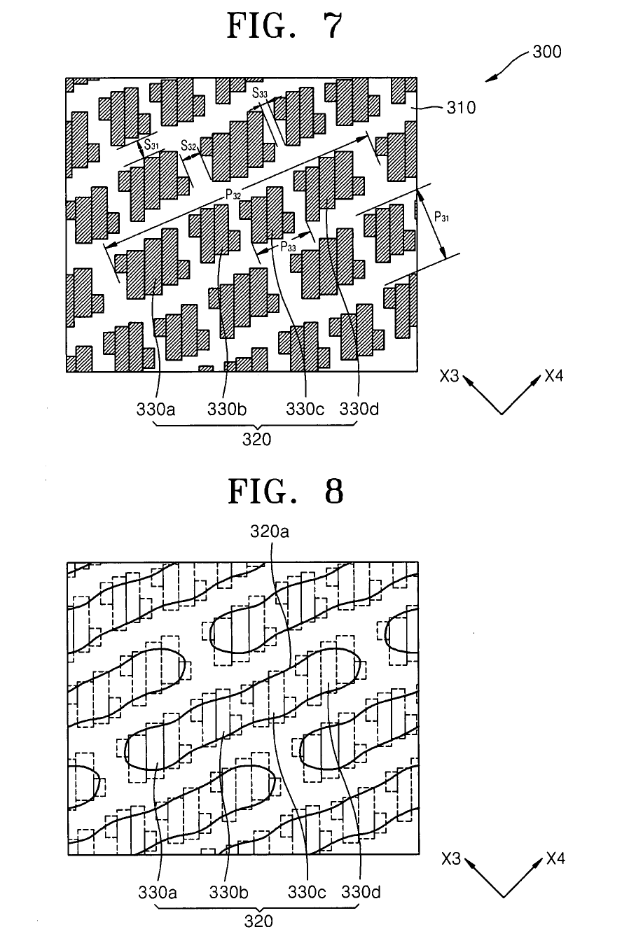

FIGS. 5 and 6 are graphs of the exposure margins of the image of FIG. 4 in the short axial direction and the long axial direction, respectively.

Referring to FIGS. 5 and 6, the EL margin is calculated as the area of the box. The EL margins are respectively calculated as about 7.8% in the short axial direction (X1-direction) and as about 6.83% in the long axial direction (X2-direction). In the simulation, the target critical dimension (CD) of the optical shielding member 220 in the X1-direction is about 70 nm and the target CD in the X2-direction is about 73 nm, and the EL margin is calculated within the range of 10% CD tolerance at the DOF of 0.15 μm.

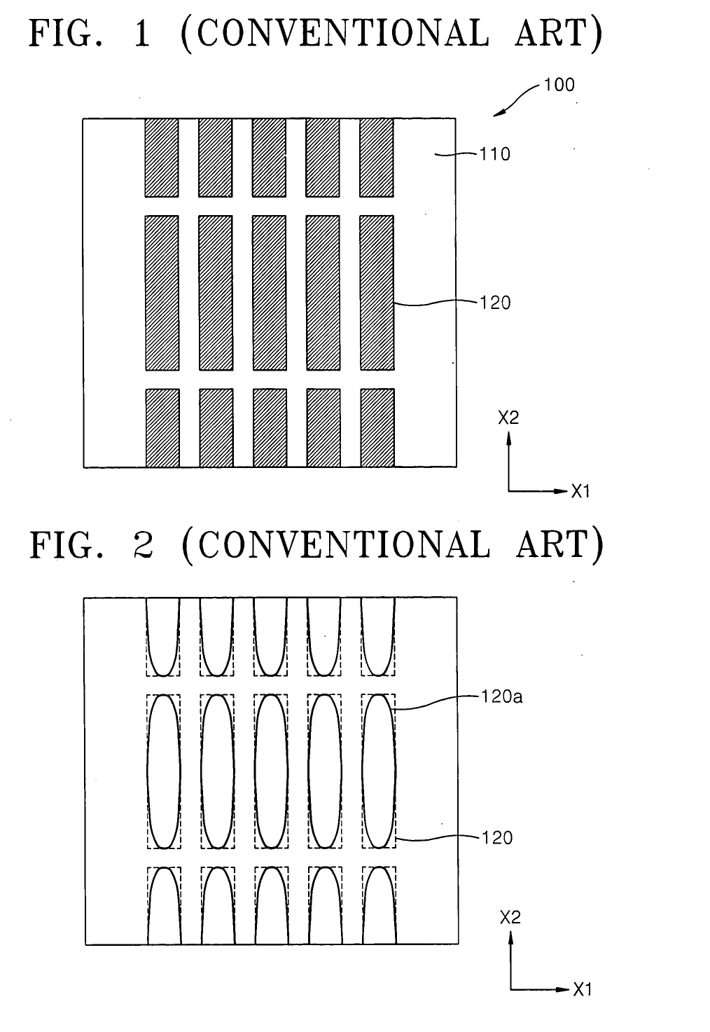

In the mask 200 in accordance with the embodiment of FIG. 3, the EL margin in the X1-direction, i.e., the short axial direction, is similar to that of the conventional mask 100 of FIG. 1 but the EL margin in the X2-direction, i.e., the long axial direction, increases from 4.77% to 6.83%, which shows about 43% improvement.

FIG. 7 is a plan view of a mask 300 for photolithography in accordance with another embodiment of the present invention. FIG. 8 is a plan view of an image 320a by simulation when photolithography is performed using the mask of FIG. 7.

The mask 300 is different from the mask 200 of FIG. 3 with respect to the direction in which optical shielding members 320 are disposed, and the shape of optical shielding layer segments 330a, 330b, 330c and 330d. Accordingly, any overlapping description of the mask 200 of FIG. 3 and the mask 300 of FIG. 7 will not be presented and only differences thereof will be described.

In FIG. 7, the mask 300 includes a transparent substrate 310 and a number of optical shielding members 320. Each optical shielding member 320 may include a plurality of optical shielding layer segments 330a, 330b, 330c and 330d which are separated from one another. The optical shielding layer segments 330a, 330b, 230c and 230d included in each optical shielding member 320 are separated from one another on the mask 300 but are connected to one another during a photolithography process, to form one image.

The transparent substrate 310 and the optical shielding members 320 may be described with reference to the description of FIG. 3. The optical shielding members 320 may have a two-dimensional shape, i.e., a shape being elongated in both the X3-direction and the X4-direction. In FIG. 7, the X3-direction indicates a short axial direction, and the X4-direction indicates a long axial direction. Each optical shielding member 320 may be disposed at a fourth pitch P₃₁ in the X3-direction and a fifth pitch P₃₂ in the X4-direction, as illustrated. The fifth pitch P₃₂ may be greater than the fourth pitch P₃₁. The optical shielding members 320 may be spaced apart from one another, at a fourth space S₃₁ in the X3-direction and a fifth space S₃₂ in the X4-direction, as illustrated.

For example, the optical shielding layer segments 330a, 330b, 330c and 330d may be formed of a plurality of square elements (not shown), considering a process of manufacturing an electron beam writing system. In FIG. 7, the elongation direction of the rectangular elements is different from the elongation direction of the optical shielding members 320. For example, the elongation direction of the square element may be parallel to a base line of the substrate, for example, a flat zone of the semiconductor substrate, on which a photoresist pattern is fabricated. In this case, the elongation direction of the optical shielding members 320, i.e., the X3-direction or X4-direction, may not be parallel to the flat zone of the semiconductor substrate on which the photoresist pattern is fabricated. For example, the mask 300 may be used upon a device isolation layer forming process to define an active region in the semiconductor substrate.

The optical shielding layer segments 330a, 330b, 330c and 330d are disposed so as to be separated from one another in the X4-direction, as illustrated. The optical shielding layer segments 330a, 330b, 330c and 330d are disposed to be spaced apart from one another, on the average, at a sixth space S₃₃ and a sixth pitch P₃₃, as illustrated. The sixth pitch P₃₃ may be similar to the fourth pitch P₃₁. For example, the difference between the sixth pitch P₃₃ and the fourth pitch P₃₁ may be within the range of 20% of the fourth pitch P₃₁. The space of the optical shielding layer segments 330a, 330b, 330c and 330d, that is, the sixth pitch S₃₃, needs to be smaller than the fourth space S₃₁ and the fifth space S₃₂, and, for example, it may be at least ½ or less.

Based on the short axial direction and the long axial direction, the fourth space S₃₁, fifth space S₃₂ and sixth space S₃₃ in the embodiment of FIG. 7 may respectively correspond to the first space S₂₁, second space S₂₂ and third space S₂₃ (FIG. 3), and the fourth pitch P₃₁, fifth pitch P₃₂ and sixth pitch P₃₃ may respectively correspond to the first pitch P₂₁, second pitch P₂₂ and third pitch P₂₃ (FIG. 3).

FIG. 8 illustrates the image 320a by simulation when photolithography is performed using the mask 300. In the simulation, the off-axis illumination system is used for an exposure process, and an ArF source is used to generate light. Although a wave shape is observed, it is noted that the optical shielding layer segments 330a, 330b, 330c and 330d are connected to one another, to form one image 320a.

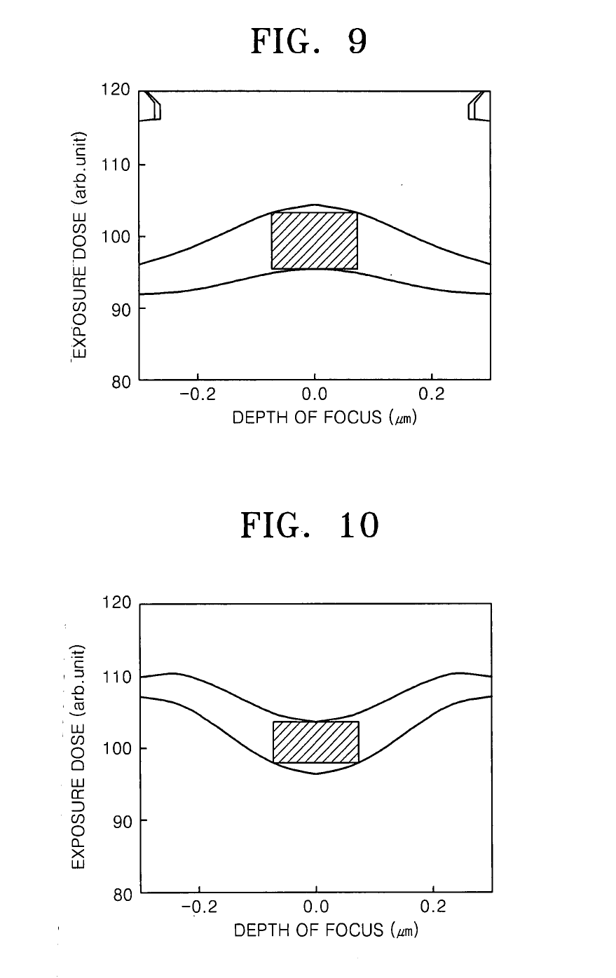

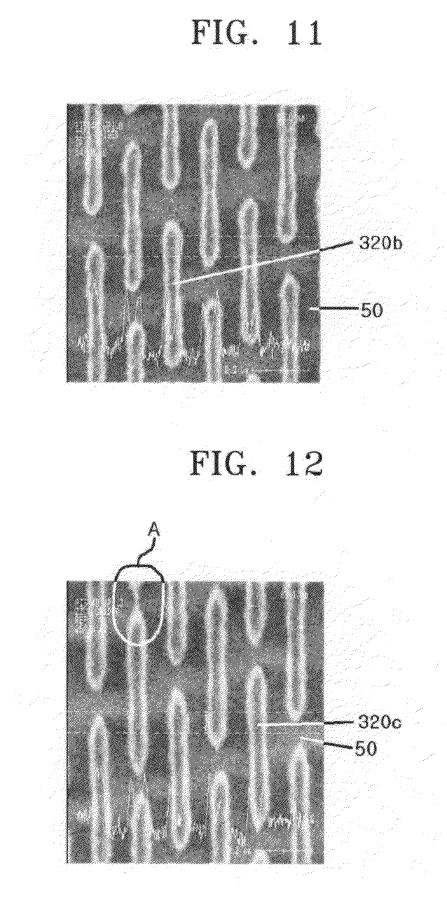

FIGS. 9 and 10 are graphs of the exposure margins of the image of FIG. 8 in the short axial direction and the long axial direction, respectively.

Referring to FIGS. 9 and 10, the EL margins are respectively calculated as about 7.68% in the short axial direction (X3-direction) and as about 5.36% in the long axial direction (X4-direction). In the simulation, the CD of the optical shielding member 320 in the X3-direction is about 64 nm and the CD in the X4-direction is about 78 nm, and the EL margin is calculated within the range of 10% CD tolerance at the DOF of 0.15 μm.

Although it is not illustrated, when a conventional mask is used, the EL margin in the X3-direction is calculated as about 7.47% and the EL margin in the X4-direction is calculated as about 1.76%. However, when the mask 300 in the embodiment of FIG. 7 is used, the EL margin in the X4-direction, i.e., the long-axial direction, increases from 1.76% to 5.36%, showing the improvement being more than about 200%. When the mask 300 in the embodiment of FIG. 7 is used, the NILS margin in the X4-direction is also improved by about 32%, compared to the conventional mask.

FIG. 11 is a plan view of a photoresist pattern 320b after photolithography is performed using the mask of FIG. 7. FIG. 12 is a plan view of a photoresist pattern after photolithography is performed using a conventional mask. The conventional mask is similar to the mask of FIG. 7 but the optical shielding layer is not divided into segment units.

In FIG. 11, the photoresist pattern 320b on substrate 50 is reliably separated without short. However, in FIG. 12, the edge of a photoresist pattern 320c in a partial region A is loosened so that the edges are almost connected to each other. Such a failure in the photoresist pattern 320c may consequently cause the short in a circuit pattern. Accordingly, the photoresist pattern 320b of the present invention shows a significantly improved profile, compared to the conventional photoresist pattern 320c.

Again referring to FIG. 11, the photoresist pattern 320b may be fabricated, for example, by the following steps:

A photoresist layer (not shown) is formed on a substrate 50. Subsequently, the photoresist layer on the substrate 50 is exposed to light, using the mask 300. During the exposure process, the light is selectively transmitted through a portion of a transparent substrate 310 where no optical shielding member 320 is positioned, so that the light is incident on a selected portion of the photoresist layer. The intensity of the light being transmitted through the portion of the transparent substrate 310 between optical shielding layer segments 330a, 330b, 330c and 330d is relatively lower than the intensity of the light being transmitted through another portion of the transparent substrate 310.

Subsequently, the photoresist layer being exposed to the light is developed, thereby fabricating a photoresist pattern 320b corresponding to an image 320a on the substrate 50. Upon the development process, the photoresist layer reacted with the light of predetermined or more intensity is selectively removed, thereby fabricating the photoresist pattern 320b. However, the development process may be performed so that the portion not reacted with the light is removed, depending on the type of the photoresist layer.

The photoresist pattern 320b may be used as a protection layer for selectively etching a thin film on the substrate 50 or on the surface of the substrate 50 or as a protection layer for selectively implanting ions into a predetermined region of the substrate 50 when a semiconductor device is fabricated.

The method of fabricating the photoresist pattern 320b by using the mask 300 of FIG. 7 may be applied to a method of fabricating a photoresist pattern by using the mask 200 of FIG. 3.

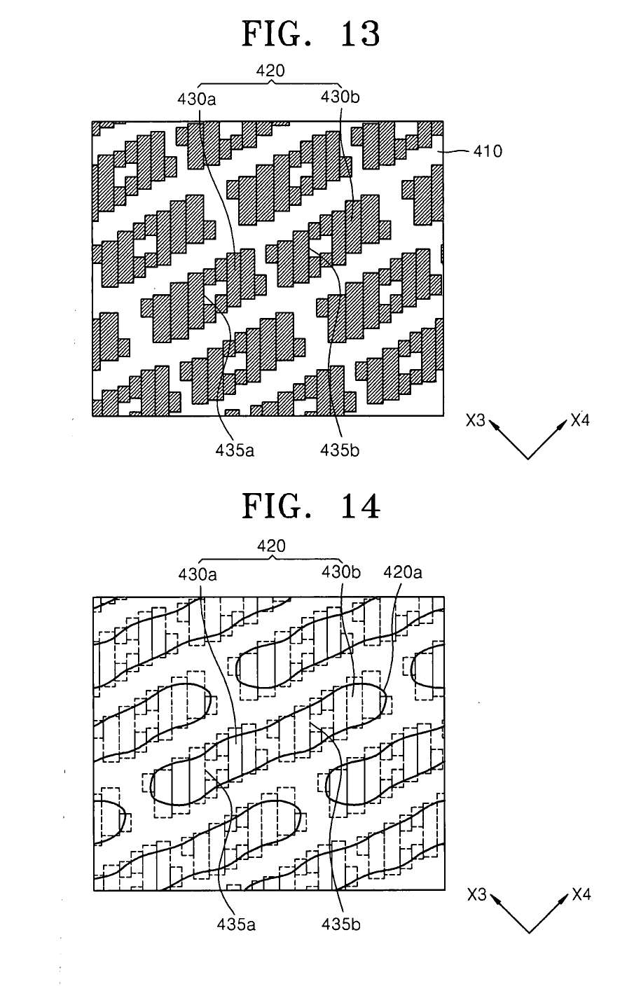

FIG. 13 is a plan view of a mask 400 for photolithography in accordance with another embodiment of the present invention. FIG. 14 is a plan view of an image 420a by simulation when photolithography is performed using the mask of FIG. 13.

The mask 400 of FIG. 13 is different from the mask 300 of FIG. 7 with respect to the direction in which optical shielding members 420 are disposed, and the number and shape of optical shielding layer segments 430a and 430b. Accordingly, any overlapping description of the mask 300 of FIG. 7 and the mask 400 of FIG. 13 will not be presented, and only differences thereof will be described.

In FIG. 13, the mask 400 includes a transparent substrate 410 and a plurality of optical shielding members 420. Each optical shielding member 420 may include a plurality of optical shielding layer segments 430a and 430b which are separated from each other. The optical shielding layer segments 430a and 430b included in each optical shielding member 420 are separated from each other on the mask 400 but are connected to each other during a photolithography process, to form one image.

The optical shielding layer segments 430a and 430b may respectively include through holes 435a and 435b for exposing the transparent substrate 410. For example, the through holes 435a and 435b may be regularly disposed within the optical shielding layer segments 430a and 430b. The through holes 435a and 435b may contribute to a decrease in the substantial pitch of each optical shielding layer segments 430a and 430b. Although FIG. 13 illustrates the through holes 435a and 435b positioned within the optical shielding layer segments 430a and 430b, the scope of the present invention shall not be limited thereto. For example, the through holes 435a and 435b may be elongated to the edges of the optical shielding layer segments 430a and 430b, and accordingly the optical shielding layer segments 430a and 430b may have a shape in that the segments are connected to each other in only one line.

FIG. 14 illustrates the image 420a by simulation when photolithography is performed using the mask 400 of FIG. 13. In the simulation, the off-axis illumination system is used for an exposure process. Although a wave shape is observed, it is noted that the optical shielding layer segments 430a and 430b are connected to each other, to form one image 420a. In this case, the EL margins are respectively measured as about 7.0% in the short axial direction (X3-axial direction) and about 5.0% in the long axial direction (X4-axial direction).

A method of fabricating a photoresist pattern by using the mask 400 in the embodiment of FIG. 13 can be performed in a manner similar to that described with respect to FIG. 11 above.

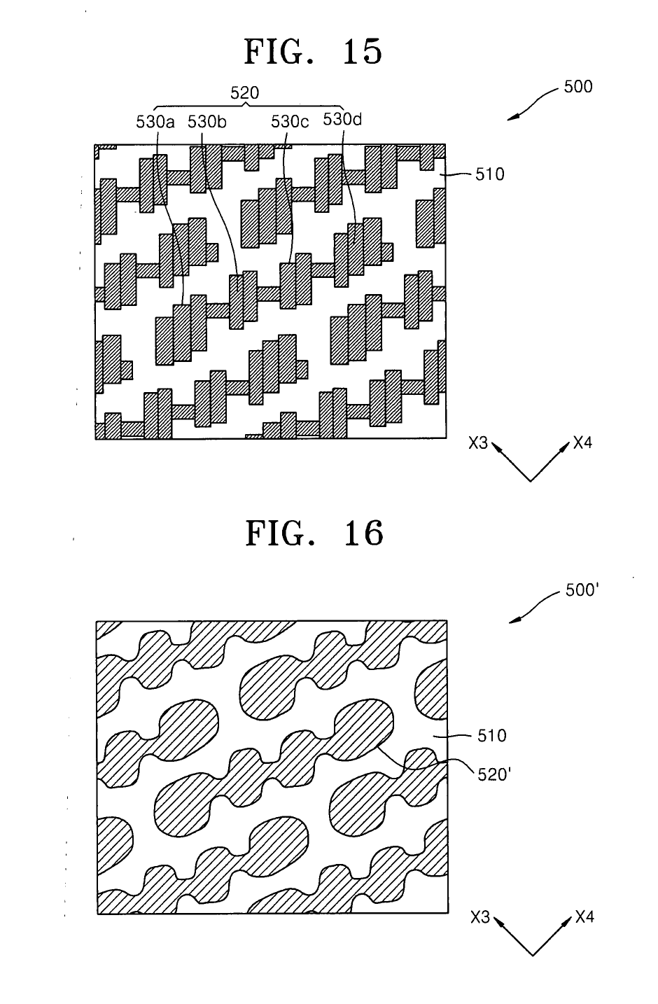

FIG. 15 is a plan view of a mask 500 for photolithography according to another embodiment of the present invention. The mask 500 of FIG. 15 is compared with the mask 300 of FIG. 7. Accordingly, any overlapping description of the embodiments of FIGS. 7 and 15 will not be presented and only differences thereof will be described.

In FIG. 15, the mask 500 includes a transparent substrate 510 and a plurality of optical shielding members 520. Each optical shielding member 520 may include a plurality of optical shielding layer segments 530a, 530b, 530c and 530d which are connected to one another in their edges. The optical shielding layer segments 530a, 530b, 530c and 530d form one image upon photolithography.

The transparent substrate 510 and the optical shielding members 520 will be understood by referring to the descriptions of FIGS. 3 and 7. The optical shielding member 520 may have a two-dimensional shape, i.e., a shape being elongated in both X3-direction and X4-direction. In FIG. 15, the X3-direction indicates a short axial direction, and the X4-direction indicates a long axial direction. A pitch in the X3-direction and a pitch in the X4-direction of the optical shielding member 520 will be understood by referring to the description of FIG. 7. That is, the pitch in the X4-direction of the optical shielding member 520 is greater than the pitch in the X3-direction for example, by at least twice or more.

The optical shielding layer segments 530a, 530b, 530c and 530d are disposed to be connected to one another in the X4 direction, as illustrated. The shape in which the optical shielding layer segments 530a, 530b, 530c and 530d are connected to one another is comparable with the shape in which the optical shielding layer segments 330a, 330b, 330c and 330d are separated from one another in FIG. 7. A width of each connection part (i.e., the element connecting 530a and 530b, the element connecting 530b and 530c, etc.) of the optical shielding layer segments 530a, 530b, 530c and 530d is smaller than a width of the other parts of each optical shielding layer segment 530a, 530b, 530c, 530d. For example, the width of the connection part thereof may be about ⅔ or less than the width of the other parts. The width of the connection part of the optical shielding layer segments 530a, 530b, 530c and 530d may be about 5 nm (based on 1X) or more by considering the limitations of manufacture but it is not restricted thereto.

A length of the optical shielding layer segments 530a, 530b, 530c and 530d may be similar to the pitch in the short axial direction of the optical shielding member 520, that is, the pitch in the X4-direction. The length of the optical shielding layer segments 530a, 530b, 530c and 530d may be understood as an average value including the connection part, based on the X4-direction. For example, the length of the optical shielding layer segments 530a, 530b, 530c and 530d may be within the range of 80 to 120% of the short axial direction of the optical shielding member 520, that is, the pitch of the X4-direction.

As described above, when the length of the optical shielding layer segments 530a, 530b, 530c and 530d is similar to the pitch in the short axial direction of the optical shielding member 520, the difference of the pitches in the short axial direction and the long axial direction of the optical shielding member 520 is off. Therefore, the exposure margins are improved as described with reference to FIGS. 3 and 7.

FIG. 16 is a plan view of a modified example of the mask for photolithography of FIG. 15.

Referring to FIG. 16, the illustrated mask 500′ has an optical shielding member 520′ that is similar to the optical shielding member 520 of FIG. 15 (i.e.,g its corner parts are curved). That is, the optical shielding members 520′ are realistically expressed, considering that the corner parts are curved when the mask 500′ is manufactured. Therefore, in the embodiments of the present invention, the corners of the optical shielding member are illustrated as being squared in shape but may be round in shape.

FIG. 17 is a plan view of an image 520a by simulation when photolithography is performed using the mask of FIG. 16.

In FIG. 17, the image 520a is obtained by simulation when performing photolithography using the mask 500′ of FIG. 16. In the simulation, an off-axis illumination system is used for an exposure process, and an ArF source is used to generate light. Optical shielding layer segments 530a, 530b, 530c and 530d are connected to one another on the whole, to form one image 520a, as illustrated.

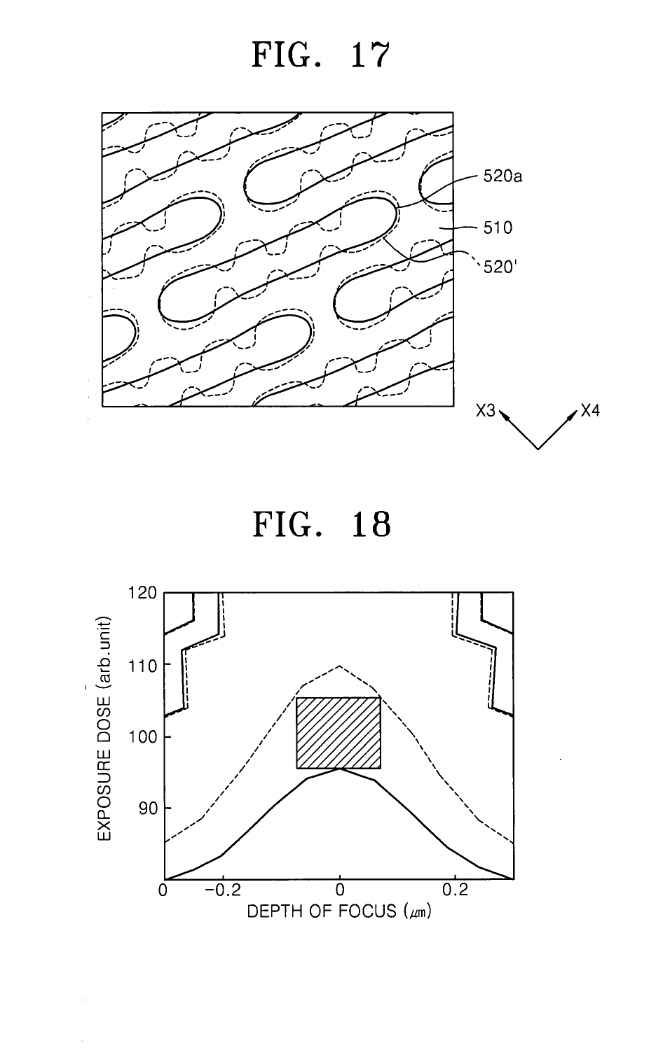

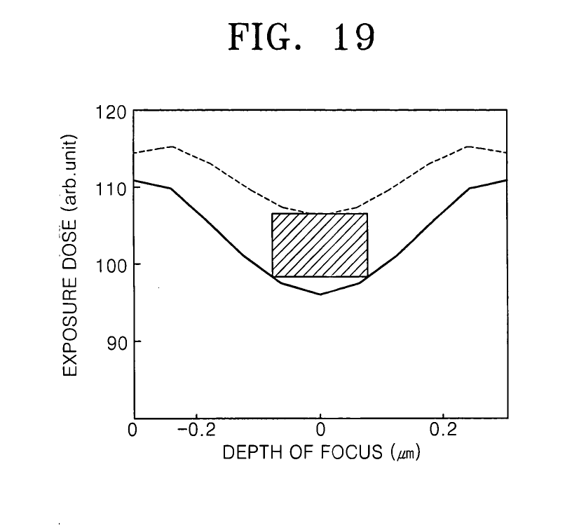

FIGS. 18 and 19 are graphs of exposure margins of the image of FIG. 17 in the short axial direction and the long axial direction, respectively.

Referring to FIGS. 18 and 19, the EL margins are respectively about 9.6% in the short axial direction (X3-direction) and about 7.8% in the long axial direction (X4-direction). In the simulation, the CD in the X3-direction of the optical shielding member 520 is about 66 nm and the CD in the X4-direction is about 80 nm. The EL margin is calculated within the range of 10% CD tolerance at the DOF of 0.16 μm. Therefore, when the mask 500′ is used, the improved EL margin is secured in the long axial direction.

A method of fabricating a photoresist pattern by using the mask of FIG. 15 or 16 will be understood referring to the description of FIG. 11.

When using a mask for photolithography in accordance with embodiments of the present invention, exposure margins are significantly improved in the photolithography process. Specifically, when forming the image of a two-dimensional pattern using the off-axial illumination technology, a mask in accordance with embodiments of the present invention significantly increases the exposure margins in the long-axial direction, for example, the EL margin and the NILS margin.

Furthermore, a photoresist pattern fabricated by using a mask in accordance with embodiments of the present invention significantly improves the problem of the short, thereby providing the high reliability. The improvement of the reliability on the photoresist pattern results in the improvement of reliability of a semiconductor device fabricated by using the photoresist pattern.

While the present invention has been particularly shown and described with reference to exemplary embodiments thereof, it will be understood by those of ordinary skill in the art that various changes in form and details may be made therein without departing from the spirit and scope of the present invention as defined by the following claims.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A photolithography mask comprising:
a transparent substrate; and
a plurality of optical shielding members on the transparent substrate;
wherein each optical shielding member includes a plurality of optical shielding layer segments which are separated from one another, wherein each optical shielding member forms one image in which the respective plurality of optical shielding layer segments are connected to one another during photolithography.

2. The photolithography mask of claim 1, wherein the plurality of optical shielding members are disposed at a first pitch in a first direction and a second pitch in a second direction, wherein the second pitch is greater than the first pitch.

3. The photolithography mask of claim 2, wherein the plurality of optical shielding layer segments are disposed along the second direction.

4. The photolithography mask of claim 3, wherein the plurality of optical shielding layer segments are disposed at a third pitch along the second direction, and wherein the difference between the first pitch and the third pitch is about 20% of the first pitch.

5. The photolithography mask of claim 2, wherein the plurality of optical shielding members are spaced apart by a first space along the first direction and are spaced apart by a second space along the second direction, wherein the plurality of optical shielding layer segments included in each optical shielding member are spaced apart from one another by a third space, and wherein the first space and the second space each are greater than the third space by a factor of 2 or more.

6. The photolithography mask of claim 1, wherein each optical shielding layer segment included in each optical shielding member includes a through hole to expose the transparent substrate.

7. The photolithography mask of claim 6, wherein the through holes are regularly disposed inside the plurality of optical shielding layer segments.

8. The photolithography mask of claim 6, wherein the through holes are elongated to the edges inside the plurality of optical shielding layer segments.

9. A method of fabricating a photoresist pattern by using the mask for photolithography of claim 1, comprising:
forming a photoresist layer on a substrate;
exposing the photoresist layer to light using the mask; and
developing the exposed photoresist layer to form a photoresist pattern corresponding to the image on a semiconductor substrate.

10. The method of claim 9, wherein exposing of the photoresist layer to light comprises utilizing an off-axis illumination technology.

11. The method of claim 9, wherein the plurality of optical shielding members of the mask used for exposure are disposed at a first pitch in a first direction and a second pitch in a section direction, and wherein the second pitch is greater than the first pitch.

12. The method of claim 11, wherein the plurality of optical shielding layer segments of the mask are disposed along the second direction.

13. The method of claim 9, wherein each of the optical shielding layer segments included in each of the plurality of optical shielding members of the mask has a through hole to expose the transparent substrate inside.

14. The method of claim 13, wherein the through holes inside the plurality of optical shielding layer segments are elongated to the edges inside the plurality of optical shielding layer segments.

15. A photolithography mask comprising:
a transparent substrate; and
a plurality of optical shielding members on the transparent substrate;
wherein each optical shielding member includes a plurality of optical shielding layer segments which are connected to one another at their edges to form one image upon photolithography; and
wherein a width of each connection part of the plurality of the optical shielding layer segments is narrower than a width of the other part.

16. The photolithography mask of claim 15, wherein the width of the connection part of the plurality of optical shielding layer segments is ⅔ or less of the width of the other part.

17. The photolithography mask of claim 15, wherein the plurality of optical shielding members are disposed at a first pitch in a first direction and at a second pitch in a second direction, and wherein the second pitch is greater than the first pitch.

18. The photolithography mask of claim 16, wherein the second pitch of the plurality of optical shielding members is greater than the first pitch by a factor of 2 or more.

19. The photolithography mask of claim 17, wherein the plurality of optical shielding layer segments are connected along the second direction.

20. The photolithography mask of claim 18, wherein a length of the plurality of optical shielding layer segments is within the range of 80% to 120% of the first pitch.
